(19) United States
(12) Patent Application Publication
(10) Pub. No.: US 2023/0282716 A1
(43) Pub. Date: Sep. 7, 2023

(54) HIGH PERFORMANCE DEVICE WITH DOUBLE SIDE CONTACTS

(71) Applicant: QUALCOMM Incorporated, San Diego, CA (US)

(72) Inventors: Qingqing LIANG, San Diego, CA (US); George Pete IMTHURN, San Diego, CA (US); Yun Han CHU, San Diego, CA (US); Sivakumar KUMARASAMY, San Diego, CA (US)

(21) Appl. No.: 17/653,481

(22) Filed: Mar. 4, 2022

(51) Int. Cl. H01L 29/417; H01L 29/423; H01L 29/78; H01L 29/40; H01L 29/66

(52) U.S. Cl. CPC H01L 29/41775; H01L 29/401; H01L 29/4175; H01L 29/42376; H01L 29/66621; H01L 29/7841

(57) ABSTRACT

Disclosed is a transistor of a device that has double side contacts in which at least a drain contact is on the opposite side of the gate. In this way, gate resistance can be reduced without increasing parasitic capacitances between gate and drain.

### FIELD OF DISCLOSURE

This disclosure relates generally to high performance devices, and more specifically, but not exclusively, to devices with double side contacts and fabrication techniques thereof.

### BACKGROUND

Integrated circuit technology has achieved great strides in advancing computing power through miniaturization of active and passive components. The package devices can be found in many electronic devices, including processors, servers, radio frequency integrated circuits, etc.

Noise figure is a key parameter in devices such as low noise amplifiers. However, this parameter is limited by gate resistance of transistors. Traditional approaches can improve the gate resistance. But such approaches can also increase undesirable parasitic capacitances.

Accordingly, there is a need for systems, apparatus, and methods that overcome the deficiencies of conventional devices including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary transistor is disclosed. The transistor may comprise a silicon (Si) layer comprising a source region, a drain region, and a channel region therebetween. The transistor may also comprise a gate oxide on the channel region on a first side of the Si layer. The transistor may further comprise a gate on the gate oxide. The transistor may yet comprise a source contact electrically coupled with the source region. The transistor may yet further comprise a drain contact on a second side of the Si layer opposite the first side of the Si layer. The drain contact may be electrically coupled with the drain region. A first gate length may be shorter than a second gate length. The first gate length may be a length of a portion of the gate closer to the gate oxide, and the second gate length may be a length of a portion of the gate further from the gate oxide.

Another exemplary transistor is disclosed. The transistor may comprise a silicon (Si) layer comprising a source region, a drain region, and a channel region therebetween. The transistor may also comprise a gate oxide on the channel region on a first side of the Si layer. The transistor may further comprise a gate on the gate oxide. The transistor may yet comprise a source contact electrically coupled with the source region. The transistor may yet further comprise a drain contact on a second side of the Si layer opposite the first side of the Si layer. The drain contact may be electrically coupled with the drain region. A center of the gate may be closer to the source region than to the drain region.

A method of fabricating a transistor is disclosed. The method may comprise forming a silicon (Si) layer comprising a source region, a drain region, and a channel region therebetween. The method may also comprise forming a gate oxide on the channel region on a first side of the Si layer. The method may further comprise a gate on the gate oxide. The method may yet comprise forming a source contact electrically coupled with the source region. The method may yet further comprise forming a drain contact on a second side of the Si layer opposite the first side of the Si layer. The drain contact may be electrically coupled with the drain region. A first gate length may be shorter than a second gate length. The first gate length may be a length of a portion of the gate closer to the gate oxide, and the second gate length may be a length of a portion of the gate further from the gate oxide.

Another method of fabricating a transistor is disclosed. The method may comprise forming a silicon (Si) layer comprising a source region, a drain region, and a channel region therebetween. The method may also comprise forming a gate oxide on the channel region on a first side of the Si layer. The method may further comprise a gate on the gate oxide. The method may yet comprise forming a source contact electrically coupled with the source region. The method may yet further comprise forming a drain contact on a second side of the Si layer opposite the first side of the Si layer. The drain contact may be electrically coupled with the drain region. A center of the gate may be closer to the source region than to the drain region.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIGS. 1A and 1B illustrate limitations of optimizing gate resistance under conventional approach of designing transistors of devices.

FIGS. 2A-2B, 3A-3B, 4A-4B and 5A-5B illustrate cross-sectional views of example transistors in accordance with one or more aspects of the disclosure.

FIGS. 6A-6F illustrate examples of stages of fabricating a transistor in accordance with one or more aspects of the disclosure.

FIGS. 7A-7D illustrate examples of alternative stages of fabricating a transistor in accordance with one or more aspects of the disclosure.

FIGS. 8-10 illustrate flow charts of an example method of manufacturing a transistor in accordance with at one or more aspects of the disclosure.

FIG. 11 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It is indicated above that noise figure (F) is a key performance parameter in devices such as radio frequency (RF) low noise amplifiers (LNA) device. However, the parameter F is limited by gate resistance (Rg) of the transistors of the LNA device. Both minimum noise figure and noise impedance (Rn) strongly depend on Rg, i.e., lower Rg leads to better minimum noise figure Fmin and noise figure F in general.

Traditional approaches can improve Rg. But the traditional approaches can also increase undesirable parasitic capacitances including gate-to-source capacitance (Cgs) and gate-to-drain capacitance (Cgd). That is, under the traditional approach, there is a tradeoff of improving some parameters at the cost of decreasing other parameters.

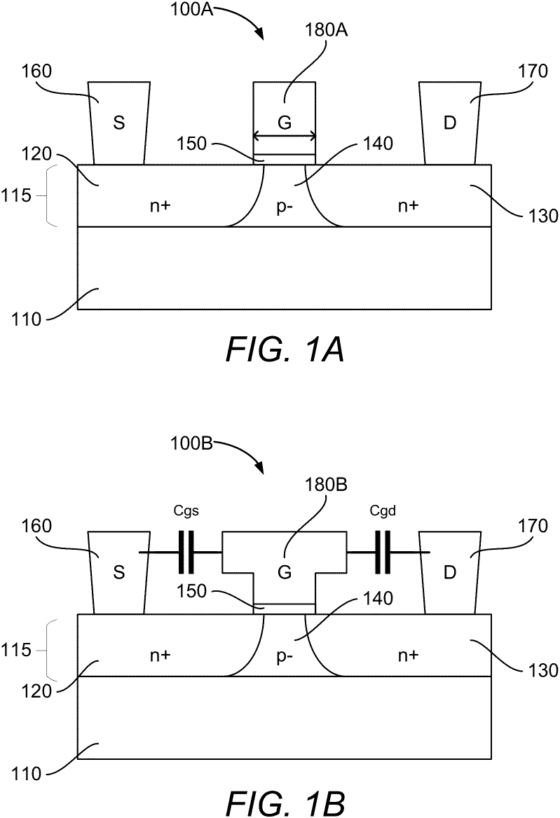

FIG. 1A illustrates a cross-section of a conventional silicon-on-insulator (SOI) transistor 100A. The transistor 100A includes a silicon (Si) layer 115 on a buried oxide (BOX) layer 110. The Si layer 115 comprises a source region 120, a drain region 130, and a channel region 140. In this instance, the transistor 100A is illustrated as an NMOS transistor. A gate oxide 150 is formed over the channel region 140, and a gate 180A is formed on the gate oxide 150. A source contact 160 is formed on the source region 120 and a drain contact 170 is formed on the drain region 130.

As noted, the gate resistance Rg has a significant effect on the noise figure F, and thus has a significant impact on the performance of the transistor. Thus, it is desirable to improve Rg to improve transistor’s performance. In general, Rg is inversely proportional to a gate length Lg. In FIG. 1A, Lg is represented by a double arrow in the gate 180A.

Thus, one way to improve Rg is to increase the effective length of the gate. This is seen in FIG. 1B which illustrates a transistor 100B showing a traditional approach to improve Rg. The transistor 100B of FIG. 1B includes components similar to that of the transistor 100A of FIG. 1A. The difference is in the gate 180B, which has a mushroom-shaped or T-shaped cross section. While the mushroom shape of the gate 180B does improve Rg of the transistor 100B, it also increases the undesirable parasitic capacitances Cgs and Cgd.

To address these and other issues related to designs of devices with conventional transistors, it is proposed to provide transistors in which the gate and at least the drain contact are on opposite side of the silicon layer. In one or more embodiments, the source contact may also be on the opposite side of the silicon layer as the gate. In one or more other embodiments, the source contact may be on the same side of the silicon layer as the gate. The proposed transistors may be used in applications such as low noise amplifiers (LNA), e.g., of a radio frequency (RF) transceiver.

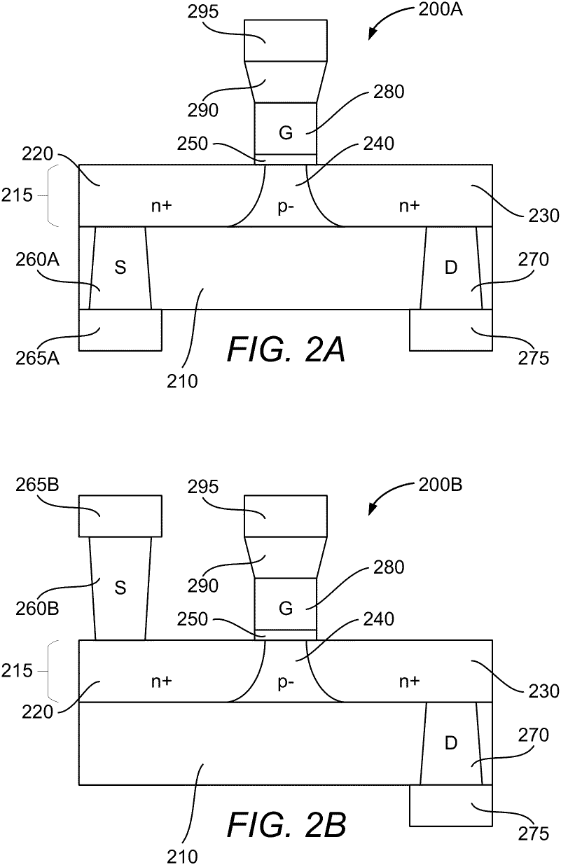

FIG. 2A illustrate cross-sectional view of a transistor 200A in accordance with one or more aspects of the disclosure. The transistor 200A may be a silicon-on-insulator (SOI) field effect transistor (FET). As seen, the transistor 200A may comprise a buried oxide (BOX) layer 210 and a silicon (Si) layer 215 on the BOX layer 210. In particular, the Si layer 215 may be on an upper surface of the BOX layer 210. It should be noted that terms or phrases such as “lower”, “upper”, “left”, “right”, “below”, “above”, “horizontal, “vertical”, etc. are used for convenience. Unless otherwise specifically indicated, such terms/phrased are not intended to indicate absolute orientations or directions.

The Si layer 215 may comprise a source region 220, a drain region 230, and a channel region 240 between the source region 220 and the drain region 230. The Si layer 215 may be doped with impurities to form the source, drain and channel regions 220, 230, 240. Transistor 200A is illustrated as being an NMOS transistor in which the source and drain regions 220, 230 are highly doped with n-type impurities. This is merely for illustration purposes and should not be taken as a limitation. That is, a PMOS transistor counterpart is fully contemplated. It should be noted that other examples of NMOS transistors will be illustrated and described. However, it should also be understood that PMOS counterparts are contemplated.

Referring back to FIG. 2A, the transistor 200A may comprise a gate oxide 250 on the channel region 240 on a first side or surface (e.g., upper side/surface) of the Si layer 215. In an aspect, the gate oxide 250 may be in direct contact with the Si layer 215 overlapping the channel region 240. The gate oxide 250 may overlap the channel region 240 at least in part. In other aspects, the gate oxide 250 may also overlap the at least a portion of the source region 220 and/or at least a portion of the drain region 230.

A gate 280 may be formed on the gate oxide 250. Thus, the gate 280 may also be on the first side of the Si layer 215. In an aspect, the gate 280 may be direct contact with the gate oxide 250. The gate 280 may be formed from electrically conductive materials such as polysilicon, metal, etc.

A source contact 260A may be formed on a second side or surface (e.g., lower side/surface) of the Si layer 215, which is opposite the first side. The source contact 260A may be formed through BOX layer 210. The source contact 260A may be electrically coupled with the source region 220. For example, the source contact 260A may be in direct contact with the source region 220 on the second side of the Si layer 215. Metals such as copper (Cu) and aluminum (Al) may be used to form the source contact 260A.

A drain contact 270 may also be formed on the second side of the Si layer 215. Similar to the source contact 260A, the drain contact 270 may be formed through BOX layer 210. The drain contact 270 may be electrically coupled with the drain region 230. For example, the drain contact 270 may be in direct contact with the drain region 230 on the second side of the Si layer 215. Metals such as copper (Cu) and aluminum (Al) may be used to form the drain contact 270.

Note that by having the source and drain contacts 260A, 270 on opposite side of the gate 280, this means that the gate 280 may be sized to improve the gate resistance Rg without increasing the undesirable parasitic capacitances Cgs and Cgd. That is, with double-side contacts, there is much more freedom to optimize the gate shape, and hence the gate resistance Rg, without degrading the parasitic capacitances Cgs and Cgd. Also, the transistor 200A (as well as other transistors described below) may be fabricated with technology that is fully compatible with advanced CMOS processes.

A gate contact 290 may be formed to be electrically coupled with the gate 280. For example, the gate contact 290 may be formed directly on the gate 280. In this way, the gate resistance Rg may be improved. The gate contact 290 may be formed from conductive metals (e.g., Cu, Al, etc.).

A gate connect 295 may be formed to be electrically coupled with the gate contact 290 (and hence with the gate 280). For example, the gate connect 295 may be formed directly on the gate contact 290. The gate connect 295 may enable electrical connections with other devices. The gate connect 295 may be formed from conductive metals (e.g., Cu, Al, etc.).

The transistor 200A may further include a source connect 265A and a drain connect 275 electrically coupled with the source contact 260A and the drain contact 270, respectively. For example, the source connect 265A may be in direct contact with the source contact 260A and/or the drain connect 275 may be in direct contact with the drain contact 270. The source and drain connects 265A, 275 may to enable electrical connections with other devices. The source connect 265A and/or the drain connect 275 may be formed from conductive metals (e.g., Cu, Al, etc.).

FIG. 2B illustrates cross-sectional view of a transistor 200B in accordance with one or more aspects of the disclosure. The transistor 200B may be similar to the transistor 200A (of FIG. 2A) except that the source contact 260B is on first side of the Si layer 215, i.e., on the same side as the gate 280.

This is due to at least the following factors. First, the parasitic capacitance Cgs between the gate and source is not as significant as the parasitic capacitance Cgd between the gate and drain. Thus, it may be tolerable to have the source contact 260B on the same side of the Si layer 215 as the gate 280. Second, in some instances, designer may want a higher Cgs to have a closer input match with the source resistance. That is, having the source contact 260B on the same side as the gate 280 may be beneficial in some respects. But in both, it is desirable to have the drain contact 270 be on the opposite side.

The transistor 200B may further include a source connect 265B electrically coupled with the source contact 260B. For example, the source connect 265B may be in direct contact with the source contact 260B. The source connect 265B may play a role similar to that of the source connect 265A. That is, the source connect 265B may to enable electrical connections with other devices. The source connect 265B may be formed from conductive metals (e.g., Cu, Al, etc.).

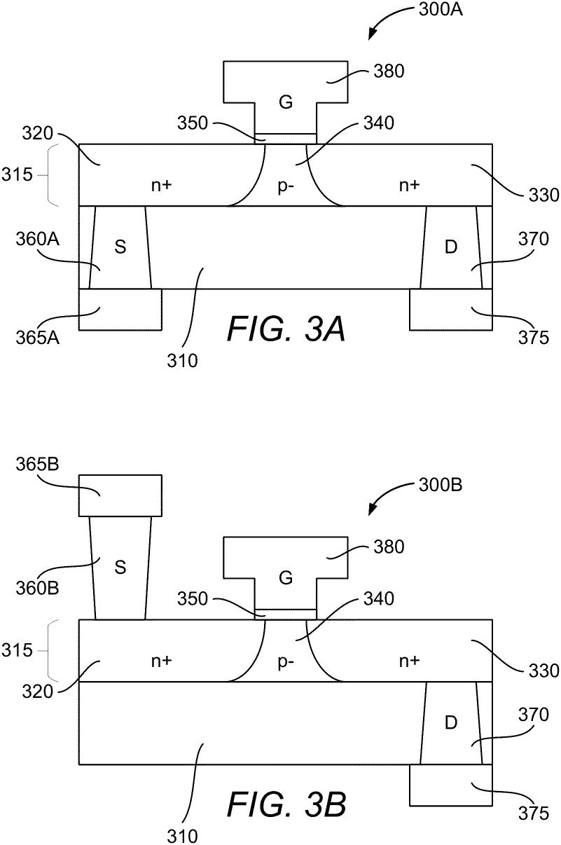

FIG. 3A illustrate cross-sectional view of a transistor 300A in accordance with one or more aspects of the disclosure. The transistor 300A may be an SOI field effect transistor. As seen, the transistor 300A may comprise a BOX layer 310 and an Si layer 315 on the BOX layer 310.

The Si layer 315 may comprise a source region 320, a drain region 330, and a channel region 340 between the source region 320 and the drain region 330. The Si layer 315 –including the source, drain and channel regions 320, 330, 340 - may be similar to the Si layer 215 including the source, drain and channel regions 220, 230, 240 of FIGS. 2A and 2B described above. Therefore, detailed descriptions thereof will be omitted for brevity.

The transistor 300A may comprise a gate oxide 350 on the channel region 340 on a first side of the Si layer 315. The gate oxide 350 may be similar to the gate oxide 250 of FIGS. 2A and 2B described above. Therefore, detailed descriptions thereof will be omitted for brevity.

A gate 380 may be formed on the gate oxide 350. Thus, the gate 380 may also be on the first side of the Si layer 315. In this instance, the gate 380 may be mushroom- or T-shaped to improve the gate resistance Rg. In an aspect, the gate 380 may be direct contact with the gate oxide 350. The gate 380 may be formed from electrically conductive materials such as polysilicon, metal, etc.

A source contact 360A may be formed on a second side of the Si layer 315. The source contact 360A may be similar to the source contact 260A of FIG. 2A described above. Therefore, detailed descriptions thereof will be omitted for brevity.

A drain contact 370 may also be formed on the second side of the Si layer 315. The drain contact 370 may be similar to the drain contact 270 of FIGS. 2A and 2B described above. Therefore, detailed descriptions thereof will be omitted for brevity.

For emphasis, it is noted that the source and drain contacts 360A, 370 are on opposite side of the gate 380 meaning that the gate 380 may be sized to improve the gate resistance Rg without increasing the undesirable parasitic capacitances Cgs and Cgd. That is, with double-side contacts, there is much more freedom to optimize the gate shape, and hence improve the gate resistance Rg, without degrading the parasitic capacitances Cgs and Cgd.

The gate 380 is one example of shaping to improve the Rg. A shape of the gate 380 may be described as follows. The gate 380 may have first and second gate lengths. The first gate length may represent the length of a portion of the gate 380 that is closer to the gate oxide 350 (e.g., lower portion of the gate 380), and the second gate length may represent the length of a portion of the gate 380 that is further from the gate oxide 350 (e.g., upper portion of the gate 380). As seen, the first gate length may be shorter than the second gate length.

While not specifically shown, a gate contact and a gate connect may be formed on the gate 380. These may be similar to the gate contact 290 and the gate connect 295. The transistor 300A may further include a source connect 365A and a drain connect 375 to enable electrical connections with other devices. The source connect 365A and the drain connect 375 may be similar to the source connect 265A and the drain connect 275 of FIG. 2A described above. Therefore, detailed description thereof will be omitted for brevity.

FIG. 3B illustrates cross-sectional view of a transistor 300B in accordance with one or more aspects of the disclosure. The transistor 300B may be similar to the transistor 300A (of FIG. 3A) except that the source contact 360B is on first side of the Si layer 315, i.e., on the same side as the gate 380. Reasons for having the source contact 360B on the same side as the gate 380 may be similar to the reasons described above with respect to the source contact 260B, and thus will not be repeated for brevity.

The transistor 300B may further include a source connect 365B electrically coupled with the source contact 360B. For example, the source connect 365B may be in direct contact with the source contact 360B. The source connect 365B may be similar to the source connect 265B of FIG. 2B, and thus the description thereof will be omitted.

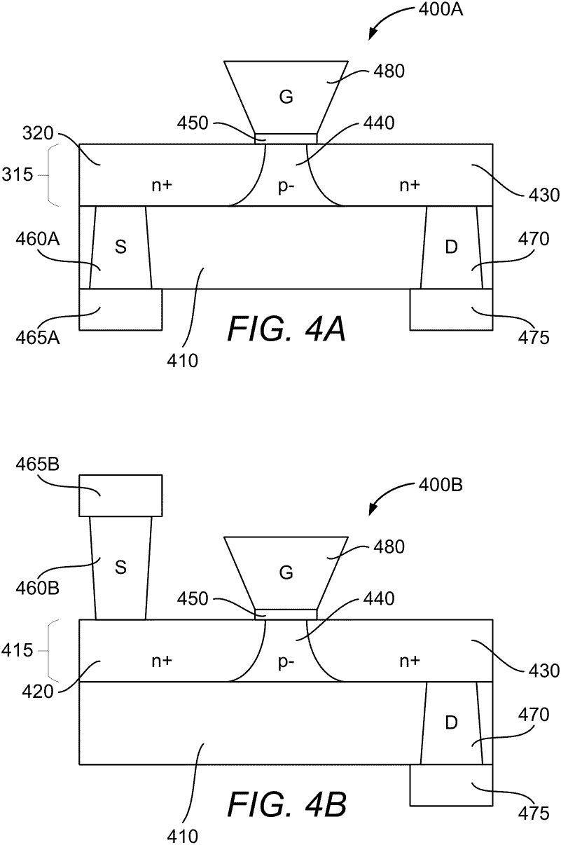

FIG. 4A illustrate cross-sectional view of a transistor 400A in accordance with one or more aspects of the disclosure. The transistor 400A may be an SOI field effect transistor. As seen, the transistor 400A may comprise a BOX layer 410 and an Si layer 415 on the BOX layer 410.

The Si layer 415 may comprise a source region 420, a drain region 430, and a channel region 440 between the source region 420 and the drain region 430. The Si layer 415 –including the source, drain and channel regions 420, 430, 440 - may be similar to the Si layer 215 including the source, drain and channel regions 220, 230, 240 of FIGS. 2A and 2B described above. Therefore, detailed descriptions thereof will be omitted for brevity.

The transistor 400A may comprise a gate oxide 450 on the channel region 440 on a first side of the Si layer 415. The gate oxide 450 may be similar to the gate oxide 250 of FIGS. 2A and 2B described above. Therefore, detailed descriptions thereof will be omitted for brevity.

A gate 480 may be formed on the gate oxide 450. Thus, the gate 480 may also be on the first side of the Si layer 415. In this instance, the gate 480 may be trapezoidal shaped to improve the gate resistance Rg. In an aspect, the gate 480 may be direct contact with the gate oxide 450. The gate 480 may be formed from electrically conductive materials such as polysilicon, metal, etc.

A source contact 460A may be formed on a second side of the Si layer 415. The source contact 460A may be similar to the source contact 260A of FIG. 2A described above. Therefore, detailed descriptions thereof will be omitted for brevity.

A drain contact 470 may also be formed on the second side of the Si layer 415. The drain contact 470 may be similar to the drain contact 270 of FIGS. 2A and 2B described above. Therefore, detailed descriptions thereof will be omitted for brevity.

Again, note that the source and drain contacts 460A, 470 are on opposite side of the gate 480 meaning that the gate 480 may be sized to improve the gate resistance Rg without increasing the undesirable parasitic capacitances Cgs and Cgd. That is, with double-side contacts, there is much more freedom to optimize the gate shape, and hence improve the gate resistance Rg, without degrading the parasitic capacitances Cgs and Cgd.

The shape of the gate 480 may be another form of the shape of the gate 380 of FIGS. 3A and 3B. That is, the shape of the gate 480 may be described as follows. The gate 480 may have first and second gate lengths. The first gate length may represent the length of a portion of the gate 480 that is closer to the gate oxide 450 (e.g., lower portion of the gate 480), and the second gate length may represent the length of a portion of the gate 480 that is further from the gate oxide 450 (e.g., upper portion of the gate 480). As seen, the first gate length may be shorter than the second gate length.

While not specifically shown, a gate contact and a gate connect may be formed on the gate 480. These may be similar to the gate contact 290 and the gate connect 295. The transistor 400A may further include a source connect 465A and a drain connect 475 to enable electrical connections with other devices. The source connect 465A and the drain connect 475 may be similar to the source connect 265A and the drain connect 275 of FIG. 2A.

FIG. 4B illustrates cross-sectional view of a transistor 400B in accordance with one or more aspects of the disclosure. The transistor 400B may be similar to the transistor 400A (of FIG. 4A) except that the source contact 460B is on first side of the Si layer 415, i.e., on the same side as the gate 480. Reasons for having the source contact 460B on the same side as the gate 480 may be similar to the reasons described above with respect to the source contact 260B, and thus will not be repeated for brevity.

The transistor 400B may further include a source connect 465B electrically coupled with the source contact 460B. For example, the source connect 465B may be in direct contact with the source contact 460B. The source connect 465B may be similar to the source connect 265B of FIG. 2B, and thus the description thereof will be omitted.

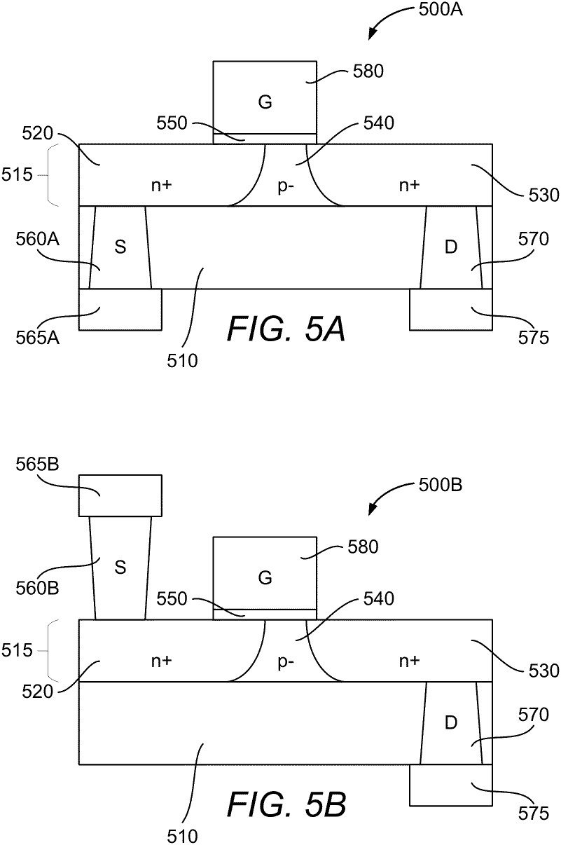

FIG. 5A illustrate cross-sectional view of a transistor 500A in accordance with one or more aspects of the disclosure. The transistor 500A may be an SOI field effect transistor. As seen, the transistor 500A may comprise a BOX layer 510 and an Si layer 515 on the BOX layer 510.

The Si layer 515 may comprise a source region 520, a drain region 530, and a channel region 540 between the source region 520 and the drain region 530. The Si layer 515 –including the source, drain and channel regions 520, 530, 540 - may be similar to the Si layer 215 including the source, drain and channel regions 220, 230, 240 of FIGS. 2A and 2B described above. Therefore, detailed descriptions thereof will be omitted for brevity.

The transistor 500A may comprise a gate oxide 550 on the channel region 540 on a first side of the Si layer 515. The gate oxide 550 may be similar to the gate oxide 250 of FIGS. 2A and 2B at least in the material that forms the gate oxides 250, 550. However, the gate oxide 550 may extend over a portion of the source region 520. That is, the gate oxide 550 may overlap at least a portion of the source region 520.

In general, a gate oxide (e.g., gate oxides 250, 350, 450, 550, etc.) may overlap at least a portion of a channel region (e.g., channel regions 240, 340, 440, 540, etc.). In some aspects, the gate oxide (e.g., gate oxides 250, 350, 450, 550, etc.) may also overlap at least a portion of a drain region (e.g., drain regions 230, 330, 430, 530). But in this instance, even if the gate oxide 550 overlaps the drain region 530, the portion of the source region 520 overlapped by the gate oxide 550 may be greater than the portion of the drain region 530 overlapped by the gate oxide 550.

A gate 580 may be formed on the gate oxide 550. Thus, the gate 580 may also be on the first side of the Si layer 515. The gate 580 may be direct contact with the gate oxide 550. The gate 580 may be formed from electrically conductive materials such as polysilicon, metal, etc. In an aspect, the gate 580 may be formed to be aligned with the gate oxide 550. Then it may be said that the portion of the source region 520 overlapped by the gate oxide 550 and the gate 580 may be greater than the portion of the drain region 530 overlapped by the gate oxide 550 and the gate 580. More generally, the gate 580 and/or the gate oxide 550 can be, but need not be, centered between the source and the drain regions 520, 530. For example, a center of the gate 580 and/or a center of the gate oxide 550 may be closer to the source region 520 than to the drain region 530.

While not shown, gates of varying shapes can have an extension over the source region greater than an extension over the drain region. For example, the mushroom-shaped gate 380 may be formed so as to have the gate oxide 350 overlap a greater portion of the source region 320 than the drain region 330. As another example, the trapezoidal shaped gate 480 may be formed so as to have the gate oxide 350 overlap a greater portion of the source region 420 than the drain region 430.

Also while not specifically shown, a gate contact and a gate connect may be formed on the gate 580. These may be similar to the gate contact 290 and the gate connect 295. The transistor 500A may further include a source connect 565A and a drain connect 575 to enable electrical connections with other devices. The source connect 565A and/or the drain connect 575 may be formed from conductive metals (e.g., Cu, Al, etc.).

A source contact 560A may be formed on a second side of the Si layer 515. The source contact 560A may be similar to the source contact 260A of FIG. 2A described above. Therefore, detailed descriptions thereof will be omitted for brevity.

A drain contact 570 may also be formed on the second side of the Si layer 515. The drain contact 570 may be similar to the drain contact 270 of FIGS. 2A and 2B described above. Therefore, detailed descriptions thereof will be omitted for brevity.

The source and drain contacts 560A, 570 are on opposite side of the gate 580 meaning that the gate 580 may be sized to improve the gate resistance Rg without increasing the undesirable parasitic capacitances Cgs and Cgd. That is, with double-side contacts, there is much more freedom to optimize the gate shape, and hence improve the gate resistance Rg, without degrading the parasitic capacitances Cgs and Cgd.

While not specifically shown, a gate contact and a gate connect may be formed on the gate 580. These may be similar to the gate contact 290 and the gate connect 295. The transistor 500A may further include a source connect 565A and a drain connect 575 to enable electrical connections with other devices. The source connect 565A and the drain connect 575 may be similar to the source connect 265A and the drain connect 275 of FIG. 2A.

FIG. 5B illustrates cross-sectional view of a transistor 500B in accordance with one or more aspects of the disclosure. The transistor 500B may be similar to the transistor 500A (of FIG. 5A) except that the source contact 560B is on first side of the Si layer 515, i.e., on the same side as the gate 580. Reasons for having the source contact 560B on the same side as the gate 580 may be similar to the reasons described above with respect to the source contact 260B, and thus will not be repeated for brevity.

The transistor 500B may further include a source connect 565B electrically coupled with the source contact 560B. For example, the source connect 565B may be in direct contact with the source contact 560B. The source connect 565B may be similar to the source connect 265B of FIG. 2B, and thus the description thereof will be omitted.

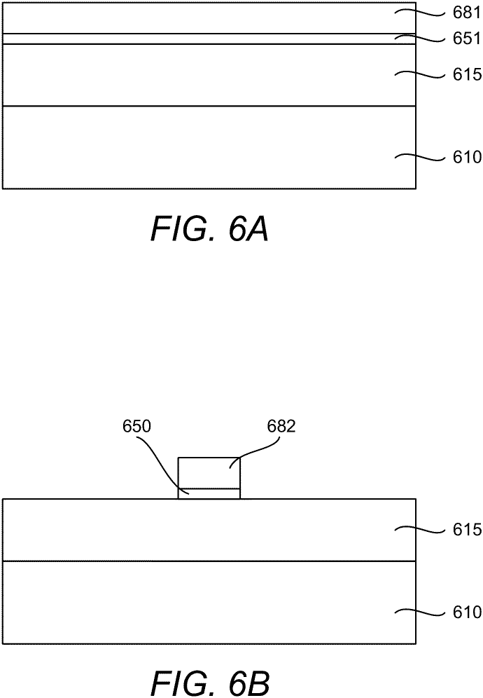

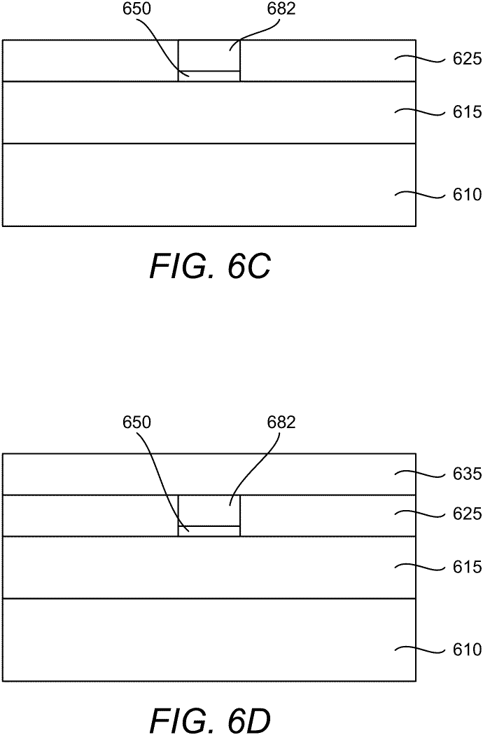

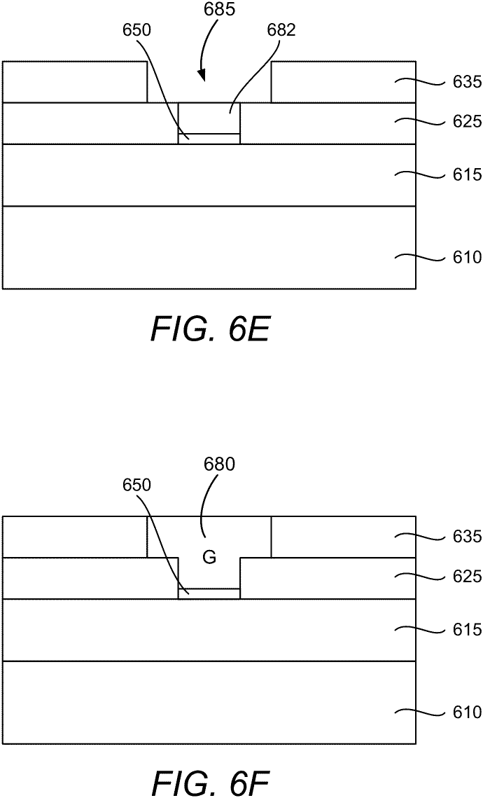

FIGS. 6A-6F illustrate examples of stages of fabricating a gate of a transistor in accordance with one or more aspects of the disclosure. In this instance, example stages of fabricating a mushroom-shaped gate (e.g., gate 380) are illustrated.

FIG. 6A illustrates a stage in which the following layers are provided – from bottom to top – an oxide layer 610 (e.g., BOX layer), a silicon (Si) layer 615 (e.g., SOI layer), a gate oxide layer 651, and a lower gate layer 681. The lower gate layer 681 may be formed from conductive materials (e.g., polysilicon, metal, etc.).

FIG. 6B illustrates a stage in which the gate oxide layer 651 and the lower gate layer 681 are etched to form a gate oxide 650 and a lower gate portion 682.

FIG. 6C illustrates a stage in which a first dielectric layer 625 is deposited on the Si layer 615 and on the lower gate portion 682, and planarized to expose the lower gate portion 682.

FIG. 6D illustrates a stage in which a second dielectric layer 635 is deposited on the first dielectric layer 625 and on the lower gate portion 682.

FIG. 6E illustrates a stage in the second dielectric layer 635 is etched (e.g., through photoresist (PR) processing) to form a gate window 685 exposing the lower gate portion 682. Note that the gate window 685 is longer than the lower gate portion 682.

FIG. 6F illustrates a stage in which an upper gate layer is deposited and planarized to fill the gate window 685 to form a gate 680. The upper gate layer may be conductive, and may be the same material as the lower gate portion 682.

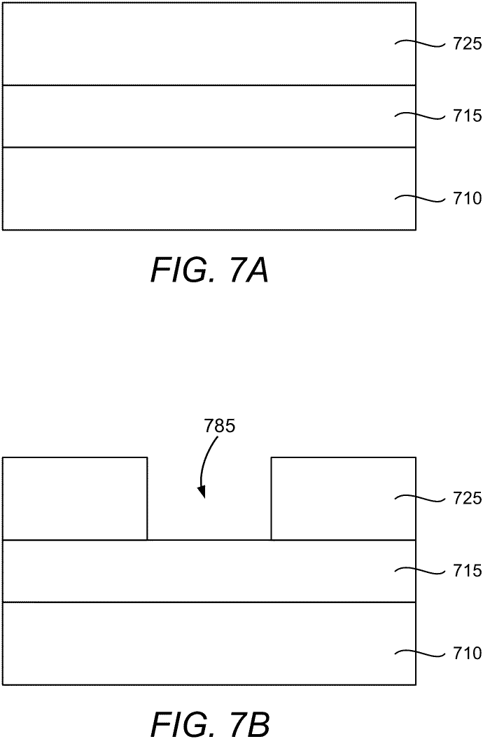

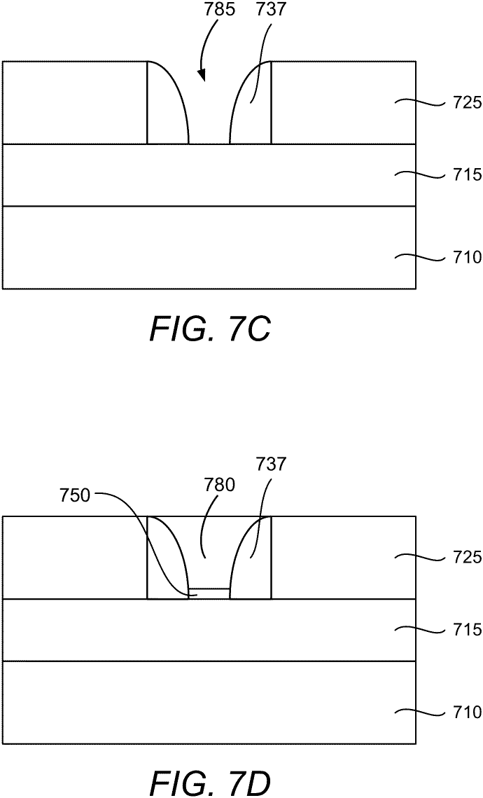

FIGS. 7A-7D illustrate examples of stages of fabricating a gate of a transistor in accordance with one or more aspects of the disclosure. In this instance, example stages of fabricating a trapezoidal gate (e.g., gate 480) are illustrated.

FIG. 7A illustrates a stage in which the following layers are provided – from bottom to top – an oxide layer 710 (e.g., BOX layer), a silicon (Si) layer 715 (e.g., SOI layer), and a dielectric layer 725.

FIG. 7B illustrates a stage in which the dielectric layer 725 is etched to form a gate window 785.

FIG. 7C illustrates a stage in which a dielectric material (same or different material from the dielectric layer 725) is deposited in the gate window 785 to form spacers 737.

FIG. 7D illustrates a stage in which oxide and conductive materials are deposited within the gate window 785 and planarized to form a gate oxide 750 and a gate 780.

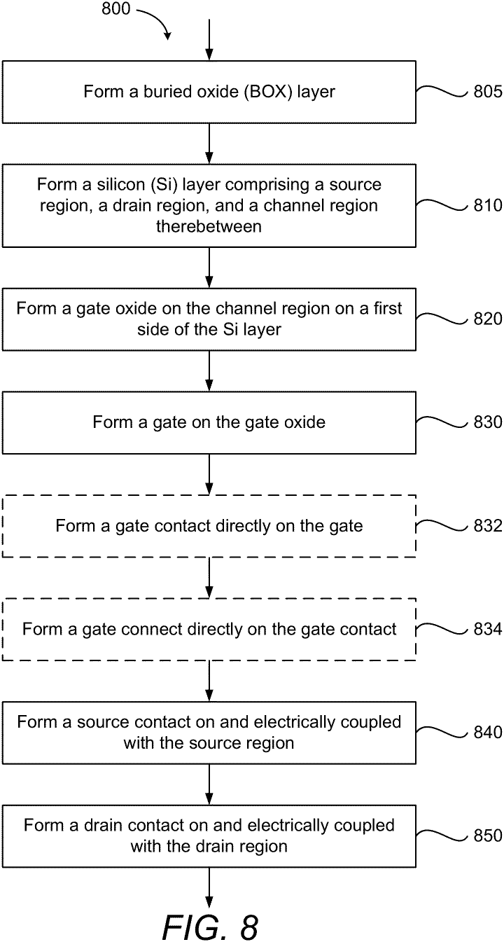

FIG. 8 illustrates a flow chart of an example method 800 of manufacturing a transistor (e.g., transistor 200A, 200B, 300A, 300B, 400A, 400B, 400A, 400B, etc.) in accordance with at one or more aspects of the disclosure. In block 805, a buried oxide (BOX) layer (e.g., BOX layer 210, 310, 410, 510, etc.) may be formed.

In block 810, a silicon (Si) layer (e.g., Si layer 215, 315, 415, 515, etc.) may be formed on the BOX layer. The Si layer may comprise a source region (e.g., source region 220, 320, 420, 520, etc.), a drain region (e.g., drain region 230, 330, 430, 530, etc.), and a channel region (channel region 240, 340, 440, 540, etc.) between the source and drain regions. In an aspect, the Si layer may be formed to be in direct contact with the BOX layer.

In block 820, a gate oxide (e.g., gate oxide 250, 350, 450, 550, etc.) may be formed on the channel region on a first side of the Si layer. The gate oxide may be in direct contact with the Si layer overlapping the channel region, at least in part. The gate oxide may also overlap the at least a portion of the source region and/or at least a portion of the drain region.

In block 830, a gate (e.g., gate 280, 380, 480, 580, etc.) may be formed on the gate oxide. The gate may be direct contact with the gate oxide, and may be formed from electrically conductive materials such as polysilicon, metal, etc.

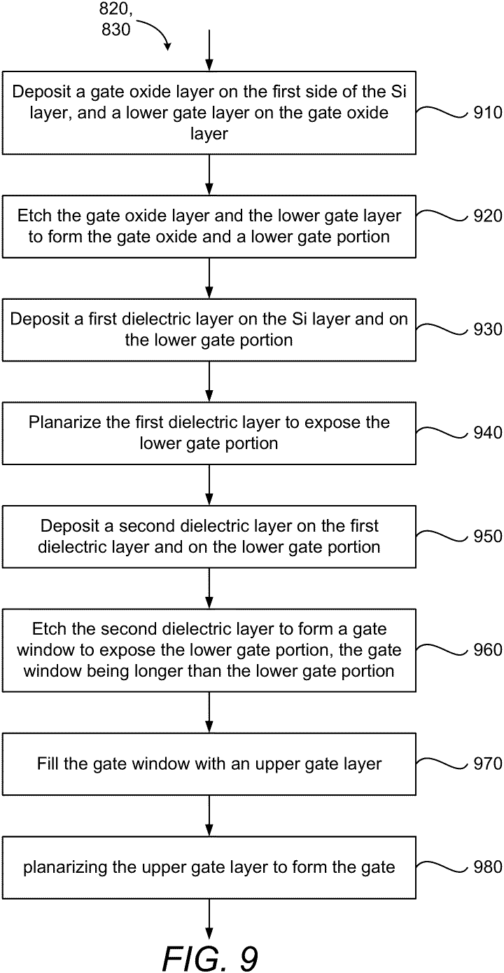

FIG. 9 illustrates a flow chart of an example process to implement blocks 820 and 830 in accordance with at one or more aspects of the disclosure. The flow chart of FIG. 9 may be directed to forming a mushroom-shaped gate (e.g., gate 380) (see also FIGS. 6A-6F).

In block 910, a gate oxide layer (e.g., gate oxide layer 651) may be deposited on the first side of the Si layer (e.g., Si layer 615), and a lower gate layer (e.g., lower gate layer 681) may be deposited on the gate oxide layer. Block 910 may correspond to the stage illustrated in FIG. 6A.

In block 920, the gate oxide layer and the lower gate layer may be etched to form the gate oxide (e.g., gate oxide 650) and a lower gate portion (e.g., lower gate portion 682). Block 920 may correspond to the stage illustrated in FIG. 6B.

In block 930, a first dielectric layer (e.g., first dielectric layer 625) may be deposited on the Si layer and on the lower gate portion.

In block 940, the first dielectric layer may be planarized to expose the lower gate portion. Blocks 930 and 940 may correspond to the stage illustrated in FIG. 6C.

In block 950, a second dielectric layer (e.g., second dielectric layer 635) may be deposited on the first dielectric layer and on the lower gate portion. Block 950 may correspond to the stage illustrated in FIG. 6D.

In block 960, the second dielectric layer may be etched to form a gate window (e.g., gate window 685) to expose the lower gate portion. The gate window may be longer than the lower gate portion 682. Block 960 may correspond to the stage illustrated in FIG. 6E.

In block 970, the gate window may be filled with a conductive upper gate layer. The upper gate layer may be the same material as the lower gate portion.

In block 980, the upper gate layer may be planarized to form the gate (e.g., gate 680). Blocks 970 and 980 may correspond to the stage illustrated in FIG. 6F.

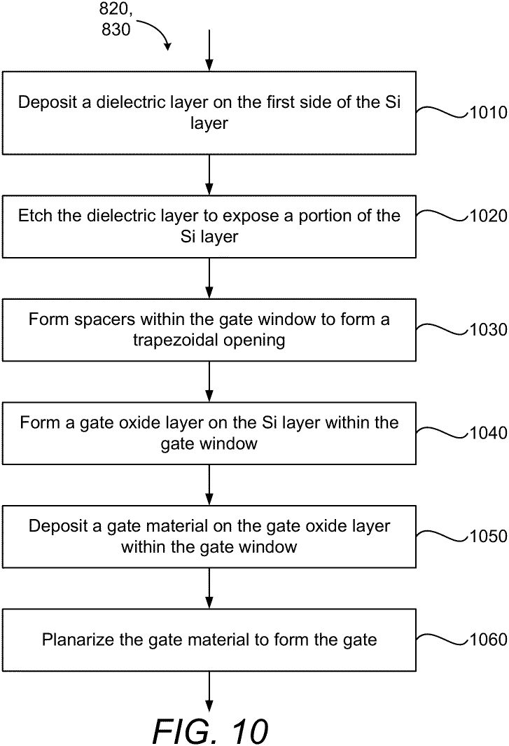

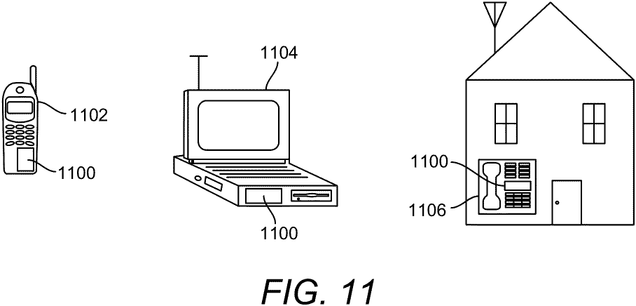

FIG. 10 illustrates a flow chart of another example process to implement blocks 820 and 830 in accordance with at one or more aspects of the disclosure. The flow chart of FIG. 10 may be directed to forming a trapezoidal shaped gate (e.g., gate 480) (see also FIGS. 7A-7D).

In block 1010, a dielectric layer (e.g., dielectric layer 725) may be deposited on a first side of the Si layer (e.g., Si layer 715). Block 1010 may correspond to the stage illustrated in FIG. 7A.

In block 1020, the dielectric layer may be etched to form a gate window (e.g., gate window 785) to expose a portion of the Si layer. Block 1020 may correspond to the stage illustrated in FIG. 7B.

In block 1030, spacers (e.g., spacers 737) may be formed within the gate window to form a trapezoidal opening. Block 1030 may correspond to the stage illustrated in FIG. 7C.

In block 1040, a gate oxide layer (e.g., gate oxide layer 750) may be formed within the gate window.

In block 1050, a conductive gate material may be deposited on the gate material within the gate window.

In block 1060, the gate material may be planarized to form the gate (e.g., gate 780). Blocks 1040, 1050, 1060 may correspond to the stage illustrated in FIG. 7D.

Referring back to FIG. 8, in block 832, a gate contact (e.g., gate contact 290) may be formed directly on the gate. More broadly, the gate contact may be formed to be electrically coupled with the gate.

In block 834, a gate connect (e.g., gate connect 295) may be formed directly on the gate contact. More broadly, the gate connect may be formed to be electrically coupled with the gate contact. Blocks 832 and 834 are dashed to indicate that the blocks are optional in one or more aspects.

In block 840, a source contact (e.g., source contact 260A, 260B, 360A, 360B, 460A, 460B, 560A, 560B, etc.) may be formed on and electrically coupled with the source region. For example, the source contact may be in direct contact with the source region. In one or more aspects, the source contact may be on a second side of the Si layer, which is opposite the first side. In this instance, the source contact may be formed through the BOX layer. In one or more other aspects, the source contact may be on the first side of the Si layer, i.e., on the same side of the Si layer as the gate.

In block 850, a drain contact (e.g., drain contact 270, 370, 470, 570, etc.) may be formed on the second side of the Si layer. The drain contact may be electrically coupled with the drain region. For example, the drain contact may be in direct contact with the source region. The drain contact may be formed through the BOX layer.

It will be appreciated that the foregoing fabrication processes and related discussion are provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations. Further, it will be appreciated that the illustrated configurations and descriptions are provided merely to aid in the explanation of the various aspects disclosed herein. For example, the number and location of the inductors, the metallization structure may have more or less conductive and insulating layers, the cavity orientation, size, whether it is formed of multiple cavities, is closed or open, and other aspects may have variations driven by specific application design features, such as the number of antennas, antenna type, frequency range, power, etc. Accordingly, the forgoing illustrative examples and associated figures should not be construed to limit the various aspects disclosed and claimed herein.

FIG. 11 illustrates various electronic devices 1100 that may be integrated with any of the aforementioned devices in accordance with various aspects of the disclosure. For example, a mobile phone device 1102, a laptop computer device 1104, and a fixed location terminal device 1106 may each be considered generally user equipment (UE) and may include one or more transistors (e.g., 200A, 200B, 300A, 300B, 400A, 400B, 500A, 500B) as described herein. The devices 1102, 1104, 1106 illustrated in FIG. 11 are merely exemplary. Other electronic devices may also include the RF filter including, but not limited to, a group of devices (e.g., electronic devices) that includes mobile devices, handheld personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A transistor, comprising: a silicon (Si) layer comprising a source region, a drain region, and a channel region therebetween; a gate oxide on the channel region on a first side of the Si layer; a gate on the gate oxide; a source contact electrically coupled with the source region; and a drain contact on a second side of the Si layer opposite the first side of the Si layer, the drain contact being electrically coupled with the drain region, wherein a first gate length is shorter than a second gate length, the first gate length being a length of a portion of the gate closer to the gate oxide, and the second gate length being a length of a portion of the gate further from the gate oxide.

Clause 2: The transistor of clause 1, further comprising: a buried oxide (BOX) layer on the second side of the Si layer, wherein the drain contact is formed through the BOX layer.

Clause 3: The transistor of any of clauses 1-2, wherein the source contact is on the first side of the Si layer.

Clause 4: The transistor of any of clauses 1-2, wherein the source contact is on the second side of the Si layer.

Clause 5: The transistor of clause 4, further comprising: a buried oxide (BOX) layer on the second side of the Si layer, wherein the source contact is formed through the BOX layer.

Clause 6: The transistor of any of clauses 1-5, wherein the gate is mushroom-shaped.

Clause 7: The transistor of any of clauses 1-5, wherein the gate is trapezoidal.

Clause 8: The transistor of any of clauses 1-7, wherein the transistor is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 9: A transistor, comprising: a silicon (Si) layer comprising a source region, a drain region, and a channel region therebetween; a gate oxide on the channel region on a first side of the Si layer; a gate on the gate oxide; a source contact electrically coupled with the source region; and a drain contact on a second side of the Si layer opposite the first side of the Si layer, the drain contact being electrically coupled with the drain region, wherein a center of the gate is closer to the source region than to the drain region.

Clause 10: The transistor of clause 9, wherein the gate oxide and the gate overlap at least a portion of the source region.

Clause 11: The transistor of clause 10, wherein the portion of the source region overlapped by the gate oxide and the gate is greater than a portion of the drain region overlapped by the gate oxide and the gate.

Clause 12: The transistor of any of clauses 9-11, further comprising: a buried oxide (BOX) layer on the second side of the Si layer, wherein the drain contact is formed through the BOX layer.

Clause 13: The transistor of any of clauses 9-12, wherein the source contact is on the first side of the Si layer.

Clause 14: The transistor of any of clauses 9-12, wherein the source contact is on the second side of the Si layer.

Clause 15: The transistor of any of clauses 9-14, wherein the transistor is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 16: A method of fabricating a transistor, the method comprising: forming a silicon (Si) layer comprising a source region, a drain region, and a channel region therebetween; forming a gate oxide on the channel region on a first side of the Si layer; forming a gate on the gate oxide; forming a source contact electrically coupled with the source region; and forming a drain contact on a second side of the Si layer opposite the first side of the Si layer, the drain contact being electrically coupled with the drain region, wherein a first gate length is shorter than a second gate length, the first gate length being a length of a portion of the gate closer to the gate oxide, and the second gate length being a length of a portion of the gate further from the gate oxide.

Clause 17: The method of clause 16, further comprising: forming a buried oxide (BOX) layer on the second side of the Si layer, wherein the drain contact is formed through the BOX layer.

Clause 18: The method of any of clauses 16-17, wherein the source contact is formed on the first side of the Si layer.

Clause 19: The method of any of clauses 16-17, wherein the source contact is formed on the second side of the Si layer.

Clause 20: The method of clause 19, further comprising: forming a buried oxide (BOX) layer on the second side of the Si layer, wherein the source contact is formed through the BOX layer.

Clause 21: The method of any of clauses 16-20, wherein the gate is mushroom-shaped.

Clause 22: The method of clause 21, wherein forming the gate oxide and forming the gate comprise: depositing a gate oxide layer on the first side of the Si layer, and a lower gate layer on the gate oxide layer; etching the gate oxide layer and the lower gate layer to form the gate oxide and a lower gate portion; depositing a first dielectric layer on the Si layer and on the lower gate portion; planarizing the first dielectric layer to expose the lower gate portion; depositing a second dielectric layer on the first dielectric layer and on the lower gate portion; etching the second dielectric layer to form a gate window to expose the lower gate portion, the gate window being longer than the lower gate portion; filling the gate window with an upper gate layer; and planarizing the upper gate layer to form the gate.

Clause 23: The method of any of clauses 16-20, wherein the gate is trapezoidal.

Clause 24: The method of clause 23, wherein forming the gate oxide and forming the gate comprise: depositing a dielectric layer on the first side of the Si layer; etching the dielectric layer to form a gate window to expose a portion of the Si layer; forming spacers within the gate window to form a trapezoidal opening; forming the gate oxide layer on the Si layer within the gate window; depositing a gate material on the gate oxide layer within the gate window; and planarizing the gate material to form the gate.

Clause 25: A method of fabricating a transistor, the method comprising: forming a silicon (Si) layer comprising a source region, a drain region, and a channel region therebetween; forming a gate oxide on the channel region on a first side of the Si layer; forming a gate on the gate oxide; forming a source contact electrically coupled with the source region; and forming a drain contact on a second side of the Si layer opposite the first side of the Si layer, the drain contact being electrically coupled with the drain region, wherein a center of the gate is closer to the source region than to the drain region.

Clause 26: The method of clause 25, wherein the gate oxide and the gate overlap at least a portion of the source region.

Clause 27: The method of clause 26, wherein the portion of the source region overlapped by the gate oxide and the gate is greater than a portion of the drain region overlapped by the gate oxide and the gate.

Clause 28: The method of any of clauses 25-27, further comprising: forming a buried oxide (BOX) layer on the second side of the Si layer, wherein the drain contact is formed through the BOX layer.

Clause 29: The method of any of clauses 25-28, wherein the source contact is formed on the first side of the Si layer.

Clause 30: The method of any of clauses 25-28, wherein the source contact is formed on the second side of the Si layer.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink / reverse or downlink / forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A transistor, comprising:
a silicon (Si) layer comprising a source region, a drain region, and a channel region therebetween;
a gate oxide on the channel region on a first side of the Si layer;
a gate on the gate oxide;
a source contact electrically coupled with the source region; and
a drain contact on a second side of the Si layer opposite the first side of the Si layer, the drain contact being electrically coupled with the drain region,
wherein a first gate length is shorter than a second gate length, the first gate length being a length of a portion of the gate closer to the gate oxide, and the second gate length being a length of a portion of the gate further from the gate oxide.

2. The transistor of claim 1, further comprising:
a buried oxide (BOX) layer on the second side of the Si layer, wherein the drain contact is formed through the BOX layer.

3. The transistor of claim 1, wherein the source contact is on the first side of the Si layer.

4. The transistor of claim 1, wherein the source contact is on the second side of the Si layer.

5. The transistor of claim 4, further comprising:
a buried oxide (BOX) layer on the second side of the Si layer, wherein the source contact is formed through the BOX layer.

6. The transistor of claim 1, wherein the gate is mushroom-shaped.

7. The transistor of claim 1, wherein the gate is trapezoidal.

8. The transistor of claim 1, wherein the transistor is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

9. A transistor, comprising:
a silicon (Si) layer comprising a source region, a drain region, and a channel region therebetween;
a gate oxide on the channel region on a first side of the Si layer;
a gate on the gate oxide;
a source contact electrically coupled with the source region; and
a drain contact on a second side of the Si layer opposite the first side of the Si layer, the drain contact being electrically coupled with the drain region,
wherein a center of the gate is closer to the source region than to the drain region.

10. The transistor of claim 9, wherein the gate oxide and the gate overlap at least a portion of the source region.

11. The transistor of claim 10, wherein the portion of the source region overlapped by the gate oxide and the gate is greater than a portion of the drain region overlapped by the gate oxide and the gate.

12. The transistor of claim 9, further comprising:
a buried oxide (BOX) layer on the second side of the Si layer, wherein the drain contact is formed through the BOX layer.

13. The transistor of claim 9, wherein the source contact is on the first side of the Si layer.

14. The transistor of claim 9, wherein the source contact is on the second side of the Si layer.

15. The transistor of claim 9, wherein the transistor is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

16. A method of fabricating a transistor, the method comprising:
forming a silicon (Si) layer comprising a source region, a drain region, and a channel region therebetween;
forming a gate oxide on the channel region on a first side of the Si layer;
forming a gate on the gate oxide;
forming a source contact electrically coupled with the source region; and
forming a drain contact on a second side of the Si layer opposite the first side of the Si layer, the drain contact being electrically coupled with the drain region,
wherein a first gate length is shorter than a second gate length, the first gate length being a length of a portion of the gate closer to the gate oxide, and the second gate length being a length of a portion of the gate further from the gate oxide.

17. The method of claim 16, further comprising:
forming a buried oxide (BOX) layer on the second side of the Si layer, wherein the drain contact is formed through the BOX layer.

18. The method of claim 16, wherein the source contact is formed on the first side of the Si layer.

19. The method of claim 16, wherein the source contact is formed on the second side of the Si layer.

20. The method of claim 19, further comprising:
forming a buried oxide (BOX) layer on the second side of the Si layer, wherein the source contact is formed through the BOX layer.

21. The method of claim 16, wherein the gate is mushroom-shaped.

22. The method of claim 21, wherein forming the gate oxide and forming the gate comprise:
depositing a gate oxide layer on the first side of the Si layer, and a lower gate layer on the gate oxide layer;
etching the gate oxide layer and the lower gate layer to form the gate oxide and a lower gate portion;
depositing a first dielectric layer on the Si layer and on the lower gate portion;
planarizing the first dielectric layer to expose the lower gate portion;
depositing a second dielectric layer on the first dielectric layer and on the lower gate portion;
etching the second dielectric layer to form a gate window to expose the lower gate portion, the gate window being longer than the lower gate portion;
filling the gate window with an upper gate layer; and
planarizing the upper gate layer to form the gate.

23. The method of claim 16, wherein the gate is trapezoidal.

24. The method of claim 23, wherein forming the gate oxide and forming the gate comprise:
depositing a dielectric layer on the first side of the Si layer;
etching the dielectric layer to form a gate window to expose a portion of the Si layer;
forming spacers within the gate window to form a trapezoidal opening;
forming a gate oxide layer on the Si layer within the gate window;
depositing a gate material on the gate oxide layer within the gate window; and
planarizing the gate material to form the gate.

25. A method of fabricating a transistor, the method comprising:
forming a silicon (Si) layer comprising a source region, a drain region, and a channel region therebetween;
forming a gate oxide on the channel region on a first side of the Si layer;
forming a gate on the gate oxide;
forming a source contact electrically coupled with the source region; and
forming a drain contact on a second side of the Si layer opposite the first side of the Si layer, the drain contact being electrically coupled with the drain region,
wherein a center of the gate is closer to the source region than to the drain region.

26. The method of claim 25, wherein the gate oxide and the gate overlap at least a portion of the source region.

27. The method of claim 26, wherein the portion of the source region overlapped by the gate oxide and the gate is greater than a portion of the drain region overlapped by the gate oxide and the gate.

28. The method of claim 25, further comprising:
forming a buried oxide (BOX) layer on the second side of the Si layer, wherein the drain contact is formed through the BOX layer.

29. The method of claim 25, wherein the source contact is formed on the first side of the Si layer.

30. The method of claim 25, wherein the source contact is formed on the second side of the Si layer.
